(19) United States
(12) Patent Application Publication
(10) Pub. No.: US 2020/0287490 A1
(43) Pub. Date: Sep. 10, 2020

(54) WIND TURBINE WITH POWER-DEPENDENT FILTER DEVICE

(71) Applicant: Wobben Properties GmbH, Aurich (DE)

(72) Inventor: Gerd BERENTS, Aurich (DE)

(21) Appl. No.: 16/648,644

(22) PCT Filed: Sep. 19, 2018
(86) PCT No.: PCT/EP2018/075272

§ 371 Date: Mar. 18, 2020

(30) Foreign Application Priority Data
Sep. 19, 2017 (DE) 10 2017 121 655.3

(51) Int. Cl. H02P 9/10; H03H 7/01; F03D 9/25

(52) U.S. Cl. CPC H02P 9/102; H02P 2101/15; F03D 9/25; H03H 7/0115

(57) ABSTRACT

Provided is a wind turbine for generating an electric power for feeding into an electric supply grid. The wind turbine includes a multiphase generator for generating electric power and a multiphase generator current and having a generator output for outputting the generator current. The turbine includes a filter device coupled to the generator output for generating a filter current, that is dependent on the electric power. The filter current influences the generator current and reduces electric oscillations thereof. The filter device includes a capacitor for influencing the filter current and at least one choke coil connected in series upstream of the capacitor for influencing the filter current. The choke coil has a saturation current value which indicates an amplitude of the filter current at which the choke coil has a magnetic saturation state. The saturation current value is less than a predetermined filter nominal current of the filter device.

### BACKGROUND

### Technical Field

The present invention concerns a wind turbine for generating electric power for feeding into an electric supply grid. The present invention also concerns a method of configuring a choke coil for use in a filter device in a wind turbine. In addition the present invention concerns a method of converting a wind turbine by retrofitting a filter device.

### Description of the Related Art

Modern wind turbines can have a large number of filter devices which are provided to reduce or prevent harmonics like, for example, unwanted harmonics in stator currents or stator voltages of a generator. Such harmonics can occur between the generator and a rectifier due to rectification. In order to counter such harmonics a filter device is fitted between the phases of the generator which is electrically connected to the rectifier.

Those traditional filter devices are comparatively large and in that respect have particularly large filter chokes or filter inductors which are expensive and which can also be of great weight. In addition by virtue of their structural configuration they have a resonance point or an unwanted resonance characteristic for certain frequencies. In addition traditional filter devices use damping resistors which can give rise to high losses for certain working ranges and possibly have to be protected from overheating with active cooling.

### BRIEF SUMMARY

As described herein the filter device in the wind turbine is permitted to be of a more compact and/or favorable configuration.

A wind turbine is provided for generating electric power for feeding into an electric supply grid. Accordingly the wind turbine includes a multiphase generator, in particular a synchronous generator, for generating electric power, the generator generating a multiphase generator current. For that purpose the generator has a generator output for outputting the multiphase generator current. The generator accordingly generates from the mechanical energy of the wind a multiphase generator current which can be provided at generator terminals at the generator output.

In that respect the generator can be operated in a lower and an upper power range. Depending on the respectively prevailing wind speed the wind turbine or the multiphase generator which is connected to rotor blades of the wind turbine by way of a mechanical shaft generates differing amount of power. The maximum power which a generator can sustainably generate is mostly its nominal power which is assumed to be 100%.

Besides the generator the wind turbine also has a filter device connected to the generator output for producing a filter current (I_{F}) for influencing the generator current, in particular for reducing electric harmonics of the generator current. The filter device is thus electrically connected to the terminals at the generator output. The filter device in that arrangement generates at least one filter current (I_{F}) at at least one phase at the generator output, in particular a respective filter current at each phase, wherein the filter current generated is dependent on the generated power of the generator. In that case the filter device generates a correspondingly higher filter current, the higher the generated power from the generator. The filter device connected to the generator output for generating the filter current includes at least one capacitor and at least one choke coil connected in series with the capacitor. Usually for a three-phase system there is provided a three-phase filter device which has three filter chokes, one per phase, and three capacitors which can be connected in a star or delta circuitry. Each filter choke is then connected between a phase and a capacitor or one of three circuit points of the star or delta circuitry. The filter current then depends on the dimensioning of the filter chokes and the capacitors. To achieve and also to thermally permit a particularly high filter current the filter chokes were hitherto selected to be very large. In that case the capacitor and the upstream-connected choke coil influence the filter current in particular in the manner of an LC filter.

The choke coil is also characterized by a saturation current value which denotes an amplitude of the filter current, at which the choke coil is in a magnetic saturation state. A choke coil or generally a coil has the so-called saturation current value as a parameter known to a person skilled in the art. When a current flows through the coil, that corresponds to the saturation current value of the coil or is higher than same, the choke coil is substantially in a so-called saturation state. The saturation state substantially occurs by virtue of the fact that a coil has a material-specific highest value in respect of magnetization or magnetic flux density B which cannot be increased just as desired by increasing the electric current through the coil.

In that respect it is proposed that the filter chokes are respectively so selected that their saturation current value is below a predetermined filter nominal current of the filter device. In that case the filter nominal current describes the current that the filter device produces when the generator is operated at nominal power. In other words the filter nominal current is generated by the filter device when the nominal power of the generator is being produced. A filter nominal current is a usual parameter of a filter, in which case the filter is usually designed for the filter nominal current so that it is not exceeded in normal operation.

In particular the choke coil is so selected that, with a filter current below the saturation current value, it exhibits a substantially inductive behavior while with a filter current above the saturation current value it exhibits a substantially ohmic behavior.

It was realized that the specific saturation behavior of a choke coil can be used in order to achieve different coil performances in dependence on the changing filter current. If a lower filter current than the saturation current value flows through the choke coil then the choke coil exhibits an inductive behavior, that is to say the choke coil has a measurable inductance, for example 100 μH. The fact that the choke coil has an inductance therefore means that it has an inductive behavior. Below the saturation current value accordingly the choke coil still presents inductance and the saturation state is not yet reached. As from when the saturation current value is reached, which in the proposed case is below a predetermined filter nominal current of the filter device, the inductance of the choke coil falls upon an increase in the filter current, for example to less than 10 microhenry (μH). Accordingly below the saturation current value the choke coil has a substantially inductive behavior—in the example 100 μH—and above the saturation current value it then has decreasingly only still a few μH, for example 10 μH. In that respect the choke coil is so designed that its saturation value is below the predetermined filter nominal current. Accordingly the choke coil in the specified example with a filter current below the saturation current value has a substantially inductive behavior while with a filter current above the saturation current value it has a substantially ohmic behavior as there the inductance has fallen.

A person skilled in the art will appreciate in that respect that the transition from inductive behavior to ohmic behavior is not a sharp transition but the inductance falls with increasing current. If for example a saturation choke is designed for a saturation current value of 30 amperes then the saturation choke could have an inductance of 100 μH and could only fall as from about 80 amperes to such an extent that the inductance is lower than 10 μH. In the specified example the inductance thus falls in a transitional range by 1.8 μH per ampere.

It is accordingly proposed that the saturation behavior of the choke coil be used in such a way that, at low filter currents, the coil has substantially an inductive behavior while with filter currents above the saturation value of the choke coil it has substantially an ohmic behavior or a very low inductance.

It was realized that significant electric oscillations can occur at low power levels of the generator, that is to say at low generator currents. Particularly in the proximity of a zero crossing of a generator current or phase current unwanted oscillations can occur, which are imposed in particular by the rectifier. They are caused for example by imprecise control of the rectifier in the lower power range when the capacitive component of the filter does not have any damping in the form of a series inductance.

Accordingly the choke coil, in particular for low generator currents, should have a substantially inductive behavior for damping the oscillations which occur. That is achieved by the inductive behavior in the lower power range of the choke coil. At higher generated power levels or generator currents significant oscillations no longer occur so that there substantially no inductive behavior on the part of the choke coil is required. By virtue of the clever design of the choke coil the choke coil then has a substantially ohmic behavior for higher generator currents or generator power levels. What is particularly advantageous with the use of a coil having the described power-dependent behavior is that the coil, by virtue of its ohmic behavior in the upper power range, also displaces the resonance point of the filter device. The intended saturation of the coil means that the inductance value is reduced and thus the resonance point of the filter device is shifted, the filter device being made of LCR components, into higher frequency ranges. Only harmonics which are negligible still occur in the higher frequency ranges so that there is no over-current at a resonance point. Conventional filter devices in contrast have a fixed resonance point so that this involves an unwanted current increase at the resonance point when the filter current has filter components which are in the region of the resonance point. That unwanted current increase was hitherto counteracted by additional damping resistors.

In a particular embodiment it is proposed that the overall interval of the generator power from 0 to 100% is subdivided into a lower and an upper power range.

According to the particular embodiment the generator in that case is operated in the lower power range when the generated power of the generator is below a power limit value. And the generator is operated in the upper power range when the generated power of the generator corresponds to or exceeds the predetermined power limit value.

If for example a predetermined power limit value of 10% of the nominal power of the generator is assumed, then the lower power range describes the power range of the generator from 0 to 10% exclusively. In that example the upper power range would then be from 10% inclusive to 100% of the nominal power. The predetermined power limit value is thus to be interpreted as a threshold value which can be related to the maximum power of the generator on a percentage basis. The predetermined power limit value can also be a predetermined current target value which describes the maximum amplitude of at least one of the generator currents. If the generator for example generates a maximum generator current of 450 A as a peak value at a nominal power of 100% then a predetermined power limit value in that case could also be a current limit value. A predetermined power limit value of 45 A (10% of 450 A) would in that case define the two power ranges in such a way that the lower power range is from 0 A to 45 A and the upper power range is from 45 A to 450 A.

According to a further embodiment it is proposed that the choke coil at a filter current below the saturation current value has a substantially inductive behavior and with a filter current above the saturation current value it has a substantially ohmic behavior.

This advantageously provides that at low filter currents, in particular in the region of zero crossings of the generator current, the choke coil involves an inductive behavior and the coil thereby reduces electric oscillations of the generator current. For greater generator currents above the saturation current the coil then behaves only still substantially like a resistor.

Preferably it is proposed that the choke coil is adapted to have a filter current flowing therethrough, which is greater than the saturation current value, in particular the choke coil being adapted to have the filter nominal current permanently flowing therethrough.

In quite general terms a choke coil or each choke coil can have flowing therethrough a current which is greater than the saturation current value. In that respect it is unusual to have a current flowing through a choke coil, which is greater than the saturation current value. If a choke coil which is not especially sized for that purpose has a current flowing therethrough which is greater than the saturation current that can result in severe heating. In a disadvantageous situation that can result in thermal damage to the choke coil. In contrast thereto the proposed choke coil is so designed that it can permanently have flowing therethrough a current greater than the saturation current value. The choke coil is designed for example by structural measures like an increased winding thickness or additional cooling sections in such a way as to achieve permanent operation in the saturation range. In addition the magnetic hysteresis losses in the core are kept low by a choice of suitable transformer plates in conformity with an applied frequency spectrum so that excessive heating does not occur in operation. In that case choke coils which are not designed explicitly as described hereinbefore to be permanently operated in a saturation state are generally not suitable for being used in a filter device in the wind turbine at the specified filter nominal currents.

In a further embodiment it is proposed that the saturation current of the choke coil is at a maximum 50%, preferably at a maximum 25%, further preferably at a maximum 10%, and particularly at a maximum 5% of the filter nominal current.

In that case therefore the saturation current of the choke coil is a percentage value related to 100% of the filter nominal current, which is generated at the nominal power of the generator. The choke coil is therefore designed with a significantly low saturation current value. Particularly with a saturation current value below a maximum of 5% of the filter nominal current but even with a saturation current value of below a maximum of 10%, that design provides that the installation operates predominantly in the saturation mode and is operated as an unsaturated choke coil only in particular situations. By virtue of that choice of the saturation threshold it is also easily possible to specifically address two operating situations, more specifically for example the lower and upper power ranges of the generator. Preferably the saturation current value is below a predetermined filter nominal current of the filter device in a range of 5% to 50% of the filter nominal current of the nominal power of the generator. It is preferably proposed that the filter device of the wind turbine is constructed without ohmic resistors, in particular damping resistors, which are respectively connected in parallel with the at least one choke coil, and in particular that the filter device does not have any damping resistors.

What is advantageous in the use of a choke coil having the above-described particular behavior in the two power ranges is that it is possible to dispense with a damping resistor, in comparison with filter devices which are already known. That damping resistor in traditional filter devices is connected in parallel with the choke coil to reduce unwantedly high filter currents which can occur in the resonance point. In that respect those damping resistors heat up in operation so that possibly active coolers like fans for cooling the resistors are required. It was recognized that, when using the proposed choke coil with an ohmic behavior in the upper power range it is possible to dispense with those damping resistors. Accordingly, in comparison with traditional filter devices, it is possible to completely dispense with the damping resistor and the cooling apparatuses for the resistor. That leads to a reduction in cost as well as a space saving in the structural configuration of the filter device.

According to a further embodiment it is proposed that the generator has one or more three-phase stator systems and for each three-phase stator system the filter device as a choke coil has a three-phase choke or three single-phase chokes with a choke path per phase and in particular a capacitor is connected to each choke path. Accordingly there are three capacitors for each three-phase stator system. In a six-phase stator system of the generator accordingly there would be six capacitors. In that case three capacitors are respectively connected in a delta or a star configuration, wherein it is particularly provided that the filter device for each three-phase stator system has as electrical components only the three-phase choke coil or three single-phase choke coils and the capacitors. It is accordingly provided that no parallel damping resistors are used for the structural configuration of the filter devices.

Nonetheless the use of the proposed choke coil with two different power ranges, in comparison with a traditional filter device, provides a similar oscillation-reducing behavior in the lower power range. In that respect the proposed filter device is of a simpler structure, with fewer components and positive resonance properties so that in particular the space required, additional components like cooling devices and costs are reduced in comparison with traditional filter devices.

It is preferably proposed that the generator is connected to a rectifier for rectifying the multiphase generator current. In that case the generator current has a plurality of phase currents with positive and negative half-waves respectively. The generator accordingly generates a multiphase alternating current (AC) voltage. The multiphase generator current is fed to a rectifier, wherein for each phase current the rectifier respectively has two thyristors for rectifying the AC voltage. The two thyristors are a positively implemented thyristor for rectifying the positive half-waves to a positive direct current (DC) voltage and a negatively implemented thyristor for rectifying the negative half-waves to a negative DC voltage. In that case a respective phase is electrically connected between the two thyristors. In that arrangement the positively implemented thyristor is actuated with a rising phase for switching on a and the negatively implemented thyristor is actuated with a falling phase for switching on. The choke coil used in the filter device or the inductance thereof is of such a dimension that it can hold a current to counteract an unwanted extinction of the respective thyristor by a phase current falling below a holding current, in particular in the proximity of a zero crossing of the phase current and in particular at low generator power levels.

It was realized that if the choke coil is of sufficiently large dimension in the proximity of a zero crossing of the phase current and with low generator power levels it is possible to achieve a significant reduction in the electric oscillations in the proximity of the zero crossing. Particularly in the proximity of a zero crossing unwanted electric oscillations occur, which are produced by the rectifier or by the rectifier device used in the rectifier like for example thyristors. Such oscillations occur for example if the thyristors used involve inaccurate control. Inaccurate control occurs in that case to an increased degree when the generator current is in the proximity of the zero crossing below the holding current of the thyristor. If the generator current or the phase current in question is less than the holding current of the thyristors the effect occurs that, although the thyristors are switched on, they independently extinguish again. Accordingly the thyristors fire a plurality of times but thereupon independently switch off again. That effect leads to electric oscillations, in particular in the proximity of the zero crossing. In order to counteract that unwanted effect the inductance of the choke coil is of such a dimension that it can hold a current in order to counteract unwanted extinction of the respective thyristor by a phase current falling below a holding current.

Furthermore, there is also proposed a method of designing a choke coil for use in a filter device in a wind turbine in accordance with at least one of the configurations described hereinbefore or hereinafter.

For that purpose the wind turbine includes a multiphase generator, in particular a synchronous generator, for generating electric power. The generator generates a multiphase generator current and the generator has a generator output for the output of the multiphase generator current. The wind turbine further includes a filter device connected to the generator output for generating a filter current (I_{F}) for influencing the generator current, in particular for reducing electric oscillations of the generator current or for compensating for a distortion reactive power. The generated filter current is dependent on the generated power of the generator and the power limit value is below a nominal value of the generator. For that purpose the filter device includes at least one capacitor for influencing the filter current and at least one choke coil connected in series upstream of the capacitor for influencing the filter current. The choke coil has a saturation current value which denotes an amplitude of the filter current, at which the choke coil has a magnetic saturation state. For that purpose the choke coil is so designed that the saturation current value is below a predetermined filter nominal current of the filter device.

Accordingly the choke coil is so designed that the saturation current value is below a predetermined filter nominal current of the filter device. If for example an inductive behavior below 10% of the filter nominal current is wanted then the design step provides that the coil is to be structurally so designed that the saturation current value of the choke coil corresponds to the desired percentage filter nominal current. As an example, a generator at 100% nominal power could generate a filter nominal current of 300 A. Now, the coil is to be so designed that the saturation current value is at 30 A (10% of the filter nominal current) and thus this involves a substantially inductive behavior of 0% to 10% exclusive of the filter nominal current. In this example, at 10% to 100% of the filter nominal current there is then a substantially ohmic behavior above the saturation value. The number of turns and the turns' thickness as well as the size and material of the core are appropriately selected.

In the specified example by way of illustration the choke coil thus has a substantially inductive behavior from 0 to 30 ampere (A) and a substantially ohmic behavior from 30 A. As described hereinbefore the transition from the lower power range into the upper power range is not abrupt but fluid. In that respect, a person skilled in the art is aware that even after the filter current exceeds the saturation current value the inductance has first fallen little and there is a transitional range in which the inductance falls in physically justified form.

It is preferably provided that the choke coil is so designed that at a filter current below the saturation current value it has a substantially inductive behavior and at a filter current above the saturation current value it has a substantially ohmic behavior. That can be achieved by the saturation current value of the coil being so selected that it corresponds to a percentage predetermined value which is below the filter nominal current.

In a further embodiment it is proposed that the saturation current of the choke coil is at a maximum 50%, preferably at a maximum 25%, further preferably at a maximum 10% and in particular at a maximum 5% of the filter nominal current.

Depending on the respective generator type the choke coil can thus be adapted to achieve the best possible reduction in oscillations with a generator current below the saturation current value. Preferably the saturation current value is in a range of 5% to 50% of the filter nominal current of the filter device which occurs at the nominal power of the generator.

In a further embodiment it is proposed that the choke coil is so designed that it is adapted to have flowing therethrough a filter current which is greater than the saturation current value and in particular the choke coil is adapted to have the filter nominal current permanently flowing therethrough. It is therefore proposed that, by virtue of its structural configuration, the choke coil can permanently have a filter current flowing therethrough, which is greater than the saturation current value. That is generally not possible with conventional choke coils. More specifically, with the usual choke coils, the saturation range is prevented from being reached at all. A general rule known to a person skilled in the art is that the saturation range is at least twice as great as the maximum current which is planned to flow through the choke. In the proposed solution however it is desired for the saturation value to be markedly below the maximum current which can flow through the choke coil. The maximum planned current which flows through the choke coil is in that case the filter nominal current.

It is preferably proposed that the design of the choke coil additionally includes the fact that iron losses of the choke coil are so selected that the filter device can be constructed without respective ohmic resistors connected in parallel with the choke coil, in particular damping resistors, in particular in such a way that the filter device for which the choke coil is intended manages without damping resistors in the intended use in the wind turbine.

By virtue of the saturation behavior the damping resistors can be omitted in the structural configuration of the filter devices. It is accordingly possible to save on costs in terms of structure and the filter device overall can be of a more compact configuration.

Further, a method of converting a wind turbine by retrofitting a filter device is proposed.

In that respect the wind turbine includes a multiphase generator, in particular a synchronous generator, for generating electric power. The generator generates a multiphase generator current and the generator has a generator output for output of the multiphase generator current. The generator is operable in a lower and an upper power range, the generator is operated in the lower power range when the generated power of the generator does not exceed a predetermined power limit value and the generator is operated in the upper power range when the generated power of the generator corresponds to or exceeds the predetermined power limit value. The wind turbine also includes a filter device connected to the generator output for generating a filter current for influencing the generator current, in particular for reducing electric oscillations of the generator current. The generated filter current is dependent on the generated power of the generator.

In regard to a wind turbine of such a structure it is now proposed that a previous filter device or a part thereof is replaced by a modified filter device or a part thereof so that the wind turbine after the conversion operation has a modified filter device. In that respect the modified filter device includes at least one capacitor for influencing the filter current and at least one choke coil connected in series upstream of the capacitor for influencing the filter current, wherein the choke coil has a saturation current value which denotes an amplitude of the filter current, at which the choke coil reaches a magnetic saturation state, and wherein the saturation current value is below a predetermined filter nominal current of the filter device.

Of the previous filter device therefore at least one filter choke or all filter chokes are replaced, more specifically in particular in each case by one having a lesser saturation current. In addition, at least as an optional step, removal of any damping resistors is carried out, in particular in such a way that thereafter there are no longer any damping resistors.

It is preferably proposed that existing choke coils are replaced by choke coils designed in accordance with one of the foregoing embodiments of the method of designing a choke coil for use in a filter device in a wind turbine and in particular damping resistors present in the previous filter device are removed.

Accordingly it is proposed that not only is the previous filter device replaced but also that in that case the damping resistors of the previous filter devices, that are not required, and also cooling devices which are no longer needed like for example fans together with actuators or ventilation openings are removed.

In accordance therewith that makes it possible for already existing wind turbines to be retrofitted with the modified filter device or for a filter device which was previously being used to be converted. The fail-safe aspect of the wind turbine is thus enhanced by the use of fewer components in the modified filter device.

### BRIEF DESCRIPTION OF THE SEVERAL VIEWS OF THE DRAWINGS

The present invention will now be described in greater detail hereinafter by way of example by means of embodiments which reference to the accompanying figures:

FIG. 1 shows a perspective view of a wind turbine;

FIG. 2 shows an illustrative view of a generator and rectifier system;

FIG. 3 shows a diagrammatic configuration of an induction value of a choke coil in dependence on the current flowing through the choke coil; and

FIGS. 4A and 4B show a comparison of a control cabinet with a conventional filter installation and a control cabinet with a filter device.

### DETAILED DESCRIPTION

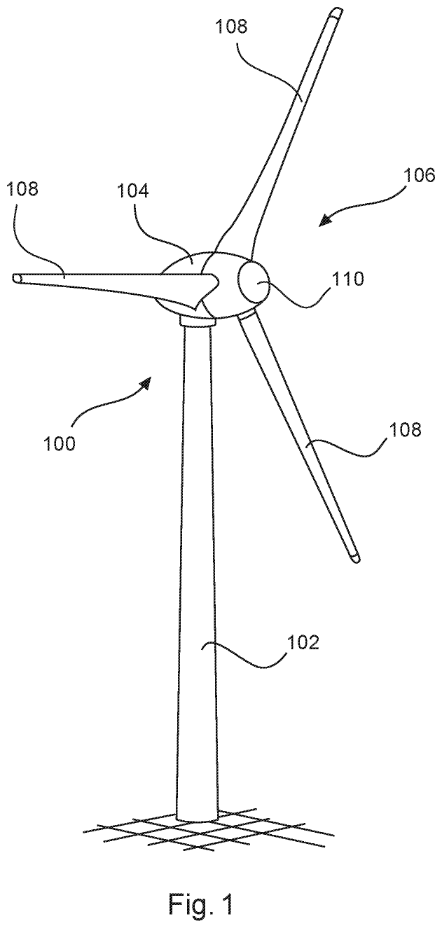

FIG. 1 shows a wind turbine 100 comprising a tower 102 and a pod 104. Arranged on the pod 104 is a rotor 106 having three rotor blades 108 and a spinner 110. The rotor 106 is driven in rotation by the wind in operation and thereby drives a generator in the pod 104.

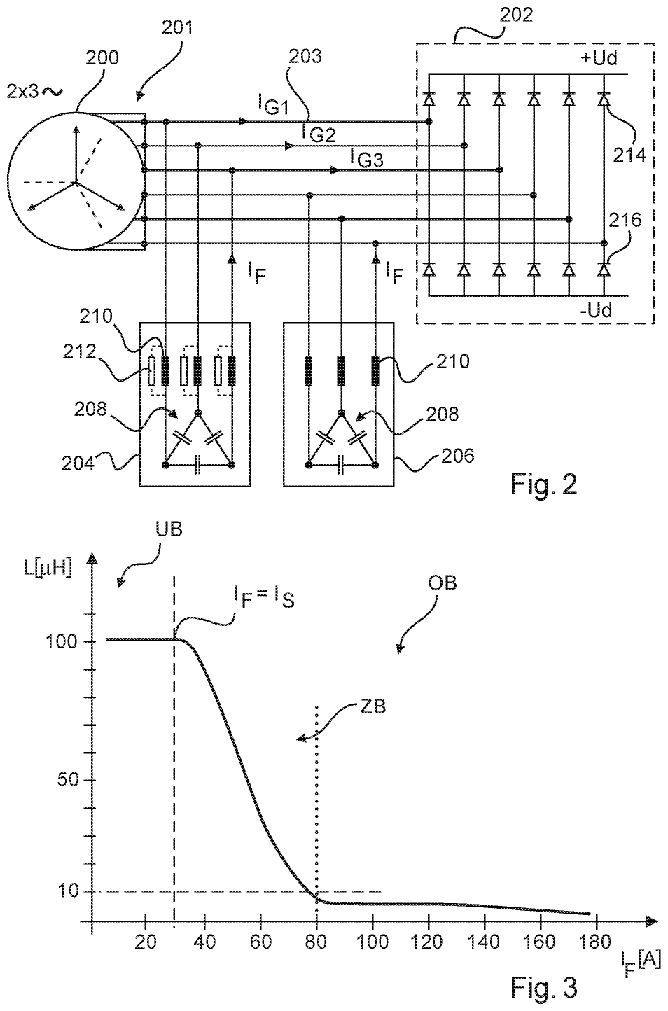

FIG. 2 shows a generator and rectifier system as of a wind turbine with a synchronous generator. In that case the generator 200 generates a six-phase generator current, of which hereinafter in particular the three phases I_{G1}, I_{G2} and I_{G3} are considered. The generator is of a six-phase configuration so that there are two three-phase stator systems. The generator 200 is connected to a rectifier unit 202 by way of six phase lines 203 extending substantially parallel. So that the phase lines 203 can be electrically coupled to the generator 200 connectors (e.g., electrical lines) are provided on the generator 200 at a generator output 201. The rectifier unit in this case is in the form of a passive rectifier. The switches can be in the form of thyristors. For each phase current two thyristors are used for rectifying the AC voltage, namely a positively implemented thyristor 214 for rectifying the positive half-waves into a positive DC voltage and a negative implemented thyristor 216 for rectifying the negative half-waves into a negative DC voltage. The generator thus has two three-phase stator systems. In that arrangement a filter device 204, 206 is connected to a respective one of the two three-phase stator systems.

The filter devices 204 and 206 shown in FIG. 2 each have three choke coils 210 and a respective capacitor network 208. The choke coil is synonymously also identified as an inductance. In accordance therewith the filter device is made up of passive components. Both filter devices 204 and 206 generate or cause a filter current I_{F} which also acts on the respective stator system. A capacitor network 208 in this case is in the form of a delta circuit. A choke coil 210 is connected upstream of the capacitor network 208. The choke coil 210 which can be in the form of a three-phase choke or in the form of three single-phase chokes has a filter current I_{F} flowing therethrough. The filter devices 204 and 206 are thus electrically connected to the generator output by way of the node points. In that way the connected filter device which is connected to the generator output can be used for generating a filter current, for reducing the electric oscillations of the generator current. Then, the AC voltage generated by the generator influences a filter current I_{F} which is dependent on the generated power of the generator, by virtue of the capacitor network 208.

In contrast to the filter device 206 the filter device 204 has indicated damping resistors 212 which are not actually connected and are only illustrated by the dotted-line connection to show the comparison with traditional filter devices. In conventional filter devices those damping resistors are used to damp LC oscillating circuits which occur. If a choke coil in accordance with the above-described embodiments is used then it is possible to dispense with those damping resistors which are arranged substantially parallel to the choke coil 210.

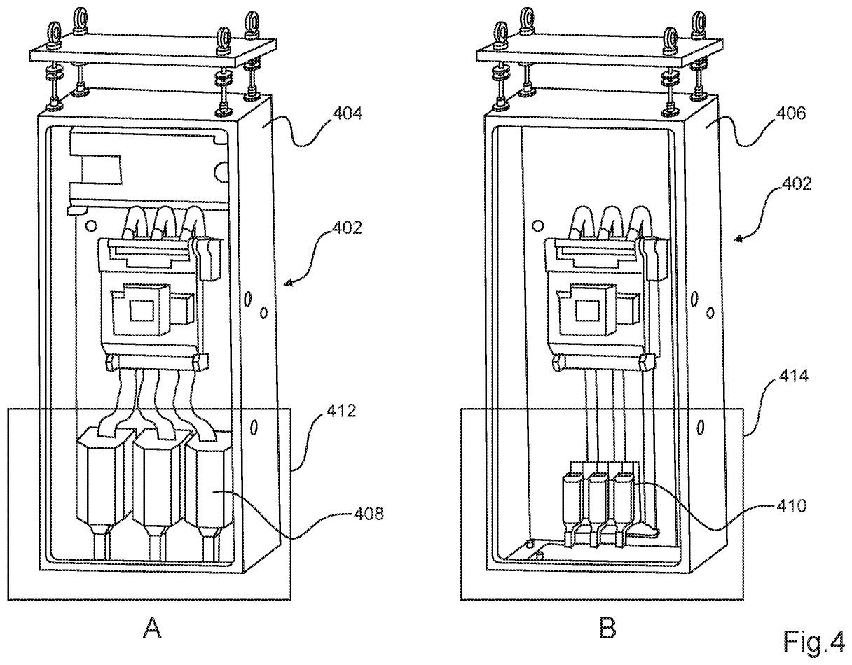

FIG. 3 shows a diagram illustrating the dependency of the inductance of the choke coil on the filter current I_{F}. For illustration purposes it has been divided into an upper power range (OB) and a lower power range (UB). For that purpose the inductance of the choke coil in μH is plotted on the ordinate and the filter current I_{F} in amperes is plotted on the abscissa. In that case the illustrated configuration of the inductance in dependence on the current has a pattern which is constant in a rough approximation in the lower power range UB.

If the saturation current value which can occur at a predetermined power limit value is reached, in the present case being 30 amperes, the inductance decreases with rising current. If the filter current corresponds to the saturation current value Is or if it is greater than the saturation current value then the upper power range OB is involved. In the illustrated example in FIG. 3 the inductance falls from 100 μH to below 10 μH in an intermediate range ZB of 30 to 80 amperes. On the assumption that the generator generates a maximum filter current I_{F} or a filter nominal current of 300 amperes at its nominal power of 100% then in the example shown in FIG. 3 the choke coil is so designed that the lower power range is from 0 to 10%, namely 30 amperes of 300. The upper power range then corresponds to 30 amperes inclusive to 300 amperes. In that case the intermediate range between 30 and 80 amperes can be associated with the upper power range in order to simplify the situation or the difference between the upper and lower power ranges. Accordingly the saturation current value of the choke coil in the illustrated embodiment in FIG. 3 is a predetermined filter nominal current of 30 A. The saturation current value is thus below the filter nominal current of 300 A or is 10% of the filter nominal current.

The saturation current value is thus to be interpreted as a definition limit value which is specified as a typical value in any technical data sheet of a coil.

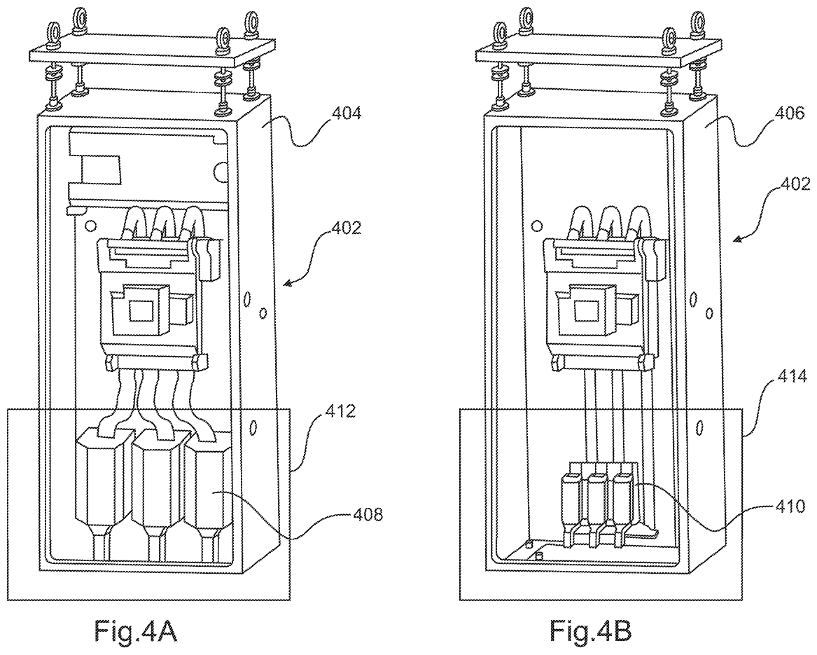

FIGS. 4A and 4B each show a filter device 400, 402 in a filter cabinet (404, 406) in a wind turbine. In this case FIG. 4A shows a conventional filter cabinet 404 without a choke coil and FIG. 4B shows a filter cabinet 406 with a choke coil. Both filter devices are intended for the same location of use, in particular for a generator and rectifier system of the same power and construction as shown in FIG. 2. FIG. 4A could show a filter device prior to conversion and FIG. 4B after conversion. If the filter chokes 408, 401 emphasized with the rectangles 412, 414 in the lower region of the two filter cabinets are compared it will be seen that the filter choke 410 in FIG. 4B can be of a substantially smaller and more compact configuration than that in FIG. 4A. The use of the proposed choke coil can thus make it possible to eliminate the damping resistors connected in parallel with the choke. In addition the filter device can be implemented with a smaller structural volume, of lesser weight and with less wiring work and cooling sections can equally be reduced in size by virtue of the lower level of lost power.

Finally advantages are briefly set forth here, which can be achieved in accordance with at least one of the foregoing embodiments, or which are at least aimed for. The use of the choke coil in the filter device can have the advantages that:
the choke coil is inductively operative only in a desired lower power range;
the choke coil displaces a resonance by saturation into non-critical frequency ranges;
the choke coil reduces the filter currents with the same harmonics behavior;
an exciter current of the generator is reduced;
the choke coil reduces current ripple in the intermediate circuit;
the filter device can be of a more advantageous, smaller and lighter structure;
the damping resistors can be eliminated by the use of the choke coil, thus components like active fans, temperature switches and surge absorbers can also be eliminated by the elimination of the damping resistors;
the housing of the filter device can be simplified;
the wiring involvement of the filter device is less;
less lost power is generated in the filter device;
the effect of the capacitive filter is increased; and
the filter device or the filter cabinets can be of a more robust structure with a higher protection rating (IP54).

1. A wind turbine for generating electric power for feeding into an electric supply grid, comprising:
a multiphase generator configured to generate the electric power, wherein the generator generates a multiphase generator current, and wherein the generator has a generator output configured to output the generator current,
a filter device coupled to the generator output and configured to generate a filter current for influencing the generator current, wherein:
the filter current is dependent on the generated electric power of the generator, and
the filter device includes:
at least one capacitor for influencing the filter current, and
a choke coil coupled in series upstream of the at least one capacitor for influencing the filter current,
wherein the choke coil has a saturation current value indicative of an amplitude of the filter current; at which the choke coil has a magnetic saturation state, and wherein the saturation current value is less than a predetermined filter nominal current of the filter device.

2. The wind turbine according to claim 1 wherein the choke coil has:
a substantially inductive behavior when the filter current is below the saturation current value, and
a substantially ohmic behavior when the filter current is above the saturation current value.

3. The wind turbine according to claim 1 wherein the choke coil is configured to have the filter current that is greater than the saturation current value flowing therethrough, and wherein the choke coil is configured to have the filter nominal current continually flowing therethrough during operation.

4. The wind turbine according to claim 1 wherein the saturation current value is between 10% and 50% of the filter nominal current.

5. The wind turbine according to claim 1 wherein the filter device does not include ohmic damping resistors connected in parallel with the choke coil.

6. The wind turbine according to claim 1 wherein:
the generator has one or more three-phase stator systems, and
for each three-phase stator system of the one or more three-phase stator systems, the filter device has a three-phase choke or three single-phase chokes with a choke path for each single-phase choke of the three single-phase chokes.

7. The wind turbine according to claim 1 wherein
the generator is coupled to a rectifier configured to rectify the generator current,
the generator current has a plurality of phase currents and each phase current of the plurality of phase currents has a positive half-wave and a negative half-wave,
the generator current is fed to the rectifier,
the rectifier, for each phase current of the plurality of phase currents, includes:
a positively-implemented thyristor configured to rectify the positive half-wave into a positive direct current voltage, and
a negatively-implemented thyristor configured to rectify the negative half-wave into a negative DC voltage, wherein:
the positive thyristor is actuated with a rising phase for switching on,
the negative thyristor is actuated with a falling phase for switching on,
inductances of the choke coils are dimensioned such that the inductances hold a current to counteract unwanted extinction of a respective thyristor by a phase current of the plurality of phase currents falling below a holding current.

8. A method of configuring a choke coil for use in a filter device, comprising:
generating, by a multiphase generator of a wind turbine, electric power, wherein the generator generates a multiphase generator current and wherein the generator has a generator output configured to output of the generator current;
generating, by a filter device coupled to the generator output, a filter current for influencing the generator current wherein the filter current is dependent on the generated electric power of the generator;
influencing, by at least one capacitor of the filter device, the filter current; and
influencing, by a choke coil of the filter device coupled in series upstream of the at least one capacitor, the filter current, wherein:
the choke coil has a saturation current value indicative of an amplitude of the filter current, at which the choke coil has a magnetic saturation state, and
the choke coil is configured such that the saturation current value is less than a predetermined filter nominal current of the filter device.

9. The method according to claim 8, comprising:
performing, by the choke coil, a substantially inductive behavior when the filter current is below the saturation current value; and
performing, by the choke coil, a substantially ohmic behavior when the filter current is greater than the saturation current value.

10. The method according to claim 8 wherein the choke coil is configured to have the filter current greater than the saturation current value flowing therethrough, and wherein the choke coil is configured to have the filter nominal current continually flowing therethrough during operation.

11. The method according to claim 8 wherein the saturation current value of the choke coil is between 10% and 50% of the filter nominal current.

12. The method according to claim 8 wherein configuring the choke coil includes:
selecting iron losses of the choke coil such that the filter device does not include damping ohmic resistors respectively connected in parallel with the choke coil.

13. A method of converting a wind turbine by retrofitting a filter device, comprising:
replacing the filter device or a part of the filter device by a modified filter device or a part of the modified filter device such that the wind turbine includes the modified filter device after the replacement, wherein the wind turbine includes:
a multiphase generator configured to generate electric power, wherein the generator generates a multiphase generator current and the generator has a generator output for outputting the generator current,
a filter device, coupled to the generator output, configured to generate a filter current for influencing the generator current and reducing electric oscillations of the generator current, wherein the filter current is dependent on the generated electric power of the generator,
wherein the modified filter device includes:
at least one capacitor for influencing the filter current; and
a choke coil connected in series upstream of the at least one capacitor for influencing the filter current, wherein the choke coil has a saturation current value indicative of an amplitude of the filter current, at which the choke coil has a magnetic saturation state, and wherein the saturation current value is less than a predetermined filter nominal current of the filter device.

14. The method of converting the wind turbine according to claim 13 wherein:
at least one filter choke or all filter chokes of the filter device are respectively replaced by a filter choke having lower saturation current, or
damping resistors are removed from the filter device such that the modified filter device does not include any damping resistors.

15. (canceled)

16. The wind turbine according to claim 1 wherein the generator is a synchronous generator.

17. The wind turbine according to claim 1 wherein the filter device is configured to generate the filter current for influencing the generator current by reducing electric oscillations of the generator current.

18. The wind turbine according to claim 6 wherein a capacitor is connected to each choke path such that the filter device includes three capacitors for each three-phase stator system of the one or more three-phase stator systems, wherein the three capacitors are coupled in a delta or a star configuration, and wherein the filter device, for each three-phase stator system of the one or more three-phase stator systems, includes, as electrical components, only a single-phase or the three-phase choke and the three capacitors.

19. The wind turbine according to claim 7 wherein the holding current is in a proximity of a zero crossing of the phase current.
